(19) United States
(12) Patent Application Publication
(10) Pub. No.: US 2026/0005082 A1
(43) Pub. Date: Jan. 1, 2026

(54) GLASS CORE EDGE TREATMENTS FOR HYBRID PANELS IN DEVICE PACKAGING

(71) Applicant: Intel Corporation, Santa Clara, CA (US)

(72) Inventors: Shayan Kaviani, Phoenix, AZ (US); Marcel Wall, Phoenix, AZ (US); Ehsan Zamani, Phoenix, AZ (US); Mahdi Mohammadighaleni, Phoenix, AZ (US); Darko Grujicic, Chandler, AZ (US); Rengarajan Shanmugam, Tempe, AZ (US); Srinivas Pietambaram, Chandler, AZ (US); Elham Tavakoli, Phoenix, AZ (US)

(73) Assignee: Intel Corporation, Santa Clara, CA (US)

(21) Appl. No.: 18/757,142

(22) Filed: Jun. 27, 2024

(51) Int. Cl. H01L 23/15; H01L 21/48; H01L 23/00; H01L 23/13; H01L 23/498

(52) U.S. Cl. CPC H01L 23/15; H01L 21/481; H01L 23/13; H01L 23/49822; H01L 23/49827; H01L 24/16; H01L 2224/16225

(57) ABSTRACT

Hybrid panel for integrated circuit (IC) package assembly that has one or more glass core panels within a perimeter frame. The hybrid panel may offer better handling characteristics during a build-up of metallization features and dielectric layers upon the glass core panels. A glass edge of a glass core panel may be physically and/or chemically treated to improve adhesion of the glass core panel to the perimeter frame, for example with an intervening organic dielectric material. In some embodiments, the glass core panel edge may be chamfered or beveled. A glass edge bevel or chamfer may further have enhanced surface roughness. In some embodiments, a glass edge is chemically functionalized with surface groups, for example through plasma oxidation. An edge-treated glass core panel may be assembled with a frame that has a complementary recessing or protruding interior sidewall adjacent to the glass core panel.

### BACKGROUND

In integrated circuit (IC) device manufacturing, IC packaging is a stage of fabrication in which an IC that has been monolithically fabricated on a chip (die or chiplet) comprising a semiconducting material is assembled into a “package” that can protect the IC chip from physical damage and support electrical contacts that connect the IC to a scaled host component. Multiple heterogenous chips can be similarly assembled, for example, into a multi-chip package (MCP).

A package substrate provides a means to connect chiplets and passives with extremely high I/O count to a host component, such as a printed circuit board (PCB). Package substrates are often built around a fiberglass resin core with copper on both sides, typically referred to as a copper clad laminate (CCL). The CCL facilitates the creation of redistribution metallization layers (RDL) that connect through the substrate core with plated through holes (PTH). The various RDLs are separated from each other by organic dielectric layers, known as build-up films, which are typically dry film laminates.

Package substrate processing has evolved beyond PCB processing through the use of specialized tooling, such laser drills, and lithography steppers that can reduce RDL feature dimensions to below 5 μm line/space (l/s). However, a transition from CCL cores to glass cores may be necessary to further scale feature sizes (e.g., to 2 μm l/s, and below) and/or to enable larger package substrate sizes (e.g., exceeding 120 mm×120 mm). For the manufacture of glass cored package substrates it would be commercially advantageous to leverage the specialized tooling that has been designed to handle large CCL panel sizes (e.g., 510 mm×515 mm and 600 mm×600 mm). Unfortunately, because of the greater fragility of glass, yields may suffer if CCL panels are simply replaced with glass panels because of many handling challenges associated with tooling developed for CCL panels.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods of forming a glass core package substrate, in accordance with some embodiments;

FIGS. 2A and 2B are plan and cross-sectional views of a glass core panel, in accordance with some embodiments;

FIGS. 3A and 3B are plan and cross-sectional views of a glass core panel following edge profiling, in accordance with some embodiments;

FIGS. 3C and 3D are cross-sectional views of a glass core panel following edge profiling, in accordance with some alternative embodiments;

FIGS. 4A and 4B are plan and cross-sectional views of a glass core panel following an edge chemical surface treatment, in accordance with some embodiments;

FIGS. 5A and 5B are plan and cross-sectional views illustrating a single glass core panel within a perimeter frame, in accordance with some embodiments;

FIGS. 5C and 5D are plan and cross-sectional views illustrating a single glass core panel within a perimeter frame, in accordance with some alternative embodiments;

FIGS. 6A and 6B are plan and cross-sectional views illustrating quarter glass core panels reconstituted within a quarter panel frame, in accordance with some embodiments;

FIGS. 7A and 7B are plan and cross-sectional views illustrating glass core units reconstituted within a unit frame, in accordance with some embodiments;

FIGS. 8A and 8B are plan and cross-sectional views illustrating a hybrid panel following lamination of a single glass core panel and frame, in accordance with some embodiments;

FIGS. 9A and 9B are plan and cross-sectional views illustrating build-up of RDL on a hybrid panel, in accordance with some embodiments;

FIGS. 10A and 10B are plan and cross-sectional view illustrating separation of a package substrate from a frame, in accordance with some embodiments;

FIG. 11 is a cross-sectional view illustrating a microelectronic device assembly including an IC package assembly including a glass core package substrate; in accordance with some embodiments;

FIG. 12 illustrates a mobile computing platform and a data server machine employing an IC package assembly including a glass core package substrate, in accordance with some embodiments; and

FIG. 13 is a functional block diagram of an electronic computing device that may be included with a mobile or server computing platform, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

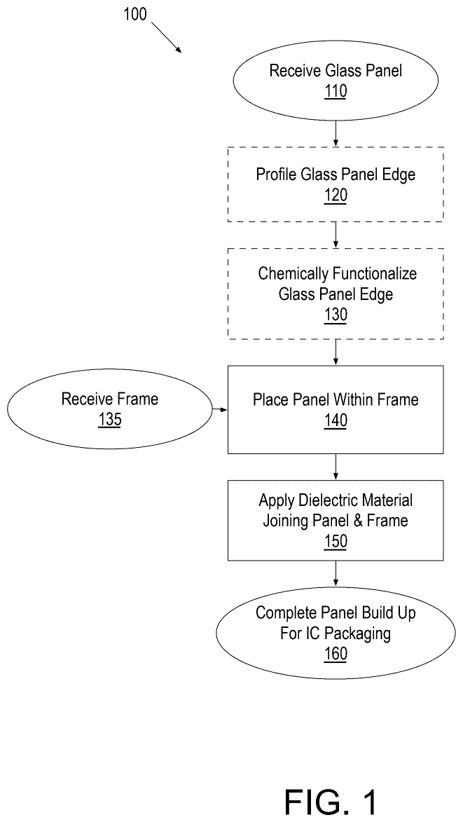

FIG. 1 is a flow diagram illustrating methods 100 for forming a glass core integrated circuit (IC) package from a hybrid panel. A hybrid panel has one or more glass core panels within a perimeter frame of a material other than glass. With the frame, a hybrid panel may offer better handling characteristics during a build-up of metallization features and dielectric layers upon the glass core panels, for example with semi-additive processes (SAP), whereby the glass core panel becomes a core of one or more built-up glass-core IC die package substrates. One or more IC die may be assembled with a glass-core substrate into an IC die package. The frame can be separated from the glass-core substrate(s) before or after IC die assembly, at which point the frame may be discarded or reused in another hybrid panel.

Methods 100 include one or more glass edge treatments performed on a glass core panel received at input 110. As described further below, the glass core panel edge treatments may improve adhesion between the glass core panel and adjacent interior edge of a frame, for example by increasing the surface area of the glass edge through profiling, increasing surface roughness of the glass edge, and/or terminating the glass edge surface(s) with one or more chemical functional groups.

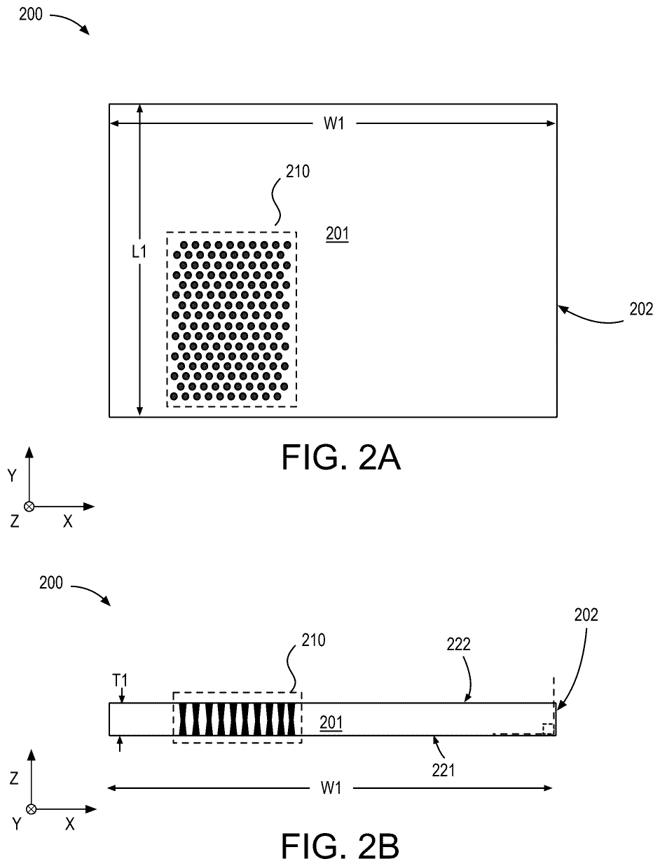

A panel of glass received as a preform at input 110 may have any composition and form factor amenable to being further processed into a glass core of a package substrate. The panel is therefore referred to herein as a “glass core panel.” FIGS. 2A and 2B are plan and cross-sectional views of a glass core panel 200, in accordance with some embodiments. The glass core panel 200 is advantageously a single bulk piece of glass 201 that is predominantly silica (e.g., silicon and oxygen) and may further include one or more compositional additives, such as, aluminum, beryllium, magnesium, calcium, strontium barium, radium, tin, sodium, silver potassium, boron, phosphorus, zirconium, lithium, titanium, or zinc. Glass 201 may therefore be any of aluminosilicate, borosilicate, alumino-borosilicate, or silica, etc. The composition of glass 201 may be primarily silicon, oxygen, and aluminum, for example. In some advantageous embodiments, glass 201 has a composition of at least 23 weight percent silicon and at least 26 weight percent oxygen, and further comprising at least 5 weight percent aluminum.

Glass 201 may have any thickness T1 between a first (e.g., bottom) glass surface 221 and a second (e.g., top) glass surface 222. In exemplary embodiments, thickness T1 is less than 2 mm, advantageously less than 1 mm and more advantageously no more than 500 μm (e.g., 100-400 μm). As a preform, glass panel 200 has a glass edge 202 that is substantially orthogonal to glass surfaces 221 and 222 over the entire glass thickness T1.

Although a glass core panel 200 may consist of only glass 201, in some embodiments glass core panel 200 further comprises non-glass structures embedded in, or formed upon, glass 201, for example upstream of methods 100 (FIG. 1). Such non-glass structures, if absent from the panel preform received at input 110, may be fabricated during the practice of methods 100. In the example illustrated in FIGS. 2A and 2B, glass core panel 200 includes a plurality of conductive through vias 210. The conductive through vias 210 extend through glass thickness T1 and are therefore referred to as through-glass vias (TGVs). In the illustrated example where glass 201 has thickness T1, metallization features, such as conductive through vias 210, intersect both opposing glass surfaces 221, 222. As shown, conductive through vias 210 may be arrayed over an area, or footprint, of glass core panel 200. Conductive through vias 210 may be arrayed over any portion of glass core panel 200. Each of conductive through vias 210 comprise a conductive material, such as a metal, embedded within the glass 201. In some examples, the metal is predominantly copper (Cu). Conductive through vias 210 may have any pitch in the x and/or y dimensions. In some embodiments, conductive through vias 210 have a pitch in at least one of x or y dimensions that is less than 5 μm, advantageously less than 2 μm, more advantageously less than 1 μm. In addition to, or in the alternative to, conductive through vias 210, glass core panel 200 may comprise other non-glass structures embedded within glass thickness T1, such as other metallization features (e.g., conductive traces or lines), IC die, MIM capacitor arrays, inductor structures, etc.

Although a glass core panel may have any lateral dimension(s), in the rectangular prism embodiments illustrated in FIGS. 2A and 2B, glass core panel 200 has a length L1 and a width W1. In some embodiments, glass core panel 200 is slightly smaller than a large format package substrate (e.g., CCL) panel, for example with a length L1 of about 510 mm and width W1 of about 515 mm. For such embodiments, a single glass core panel 200 may be incorporated into a single hybrid panel that is approximately the same size as a large format package substrate panel. In alternative embodiments where a plurality of glass core panels 200 are reconstituted within a perimeter frame, length L1 and width W1 may each be scaled down (e.g., to an approximate 200-250 mm quadrant of a large format package substrate panel, or an approximate 100-125 mm 1/16^{th} sector of a large format package substrate panel). Regardless of size, each glass core panel 200 may either be retained as a single unit that is subsequently incorporated into a single IC die package assembly, or each glass core panel 200 may be subsequently cut down into multiple units such that different portions of a single glass core panel 200 is incorporated into different IC die package assemblies.

Returning to FIG. 1, methods 100 continue with one or more edge profiling processes at block 120. Block 120 is illustrated in dashed line to emphasize edge profiling is optional in methods 100. Edge profiling may, for example, increase surface area of the edge and/or improve physical containment of adhesive material subsequently applied to the panel edge. Increasing the edge surface area may increase the yield strength of an adhesive in contact with the edge, for example. Block 120 may comprise macroscopic profiling where an edge of the glass panel received at input 110 is made non-orthogonal to the front and/or back surfaces of the glass. Block 120 may also, or in the alternative, comprise microscopic profiling where an edge of the glass panel received at input 110 is roughened, for example to be substantially rougher than a front and/or back side of a glass core panel.

In exemplary embodiments, glass edge profiling performed at block 120 chamfers or bevels a glass core panel edge from one or more of the front or back side surfaces of the glass. Any techniques suitable for etching or physically machining glass, including any processes enlisted in the fabrication of TGVs may, be practiced at block 120. Edge profiling performed at block 120 may, for example, include one or more processes, such as, but not limited to, wet chemical glass etching (e.g., with an edge bead removal process where angled spray nozzles spray a wet etchant directional spray with NaOH or HF), laser-assisted (enhanced) deep glass etching, dry (plasma) glass etching, or mechanical glass grinding/polishing. Depending on the process(es) practiced to profile the glass edge, a mask material may be optionally applied prior to edge profiling to protect front and/or back surfaces of a glass core panel during edge processing.

For some exemplary embodiments where laser-assisted etching is practiced, a perimeter of a panel is exposed to laser energy that modifies the glass, for example altering its microstructure. Rather than ablating the glass, laser modification of the glass enables the glass to be subsequently removed with an etchant that is selective to other regions of glass that did not receive the laser energy. Modification of the glass may, for example, form nanopores that accelerate wet chemical etching.

In some embodiments, the laser is an ultrashort (e.g., picosecond) pulsed laser operated at pulse durations of around 5 ps. Laser exposure energy may vary with implementation, but in some examples pulse energies are greater than 1000 nJ. Pulse repetition rates may also vary with an exemplary range being 50-250 kHz (e.g., 105 kHz). Although the laser energy may be electromagnetic radiation of any wavelength, in some embodiments the laser energy is in the near-IR range with 1030 nm being one example. Following laser exposure, a glass core panel may be exposed a wet chemical solution (e.g., comprising potassium hydroxide) and regions exposed to the laser energy may etch at a rate significantly greater than (e.g., 100-500 times) that of unmodified regions of the glass.

In some further embodiments, glass edge profiling at block 120 comprises increasing an average surface roughness of the edge. Edge surface roughening may comprise any techniques known to be suitable for glass of the type received at input 110 with some examples including abrasive process(es), laser texturing, electrochemical discharge machining, electrochemical etching, or plasma etching. In some embodiments, profiling performed to macroscopically alter the edge profile concurrently increases edge surface roughness although block 120 may also entail only edge roughening. Depending on the roughening processes performed at block 120, roughness may vary from nanometer to micrometer scale.

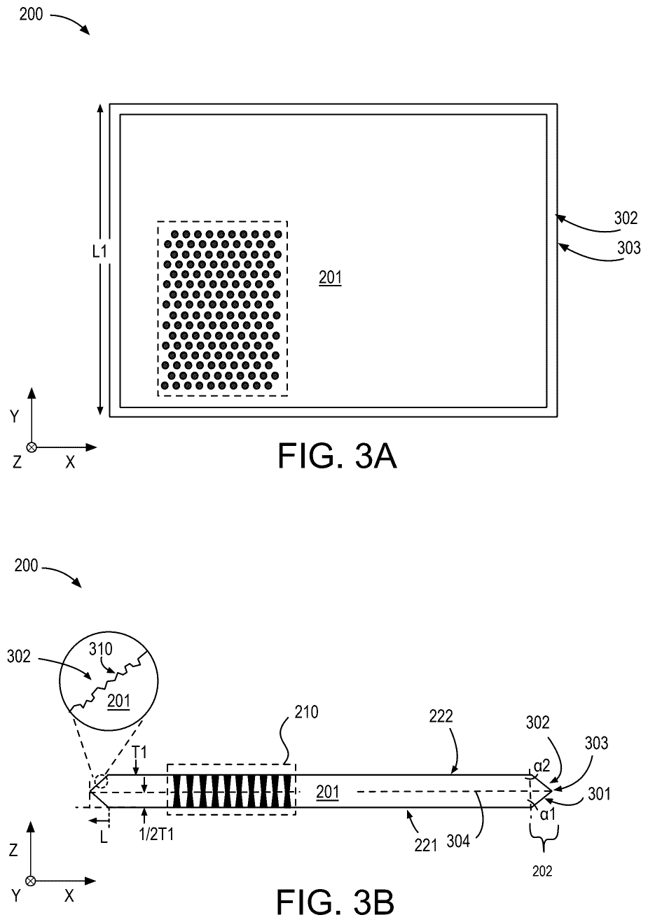

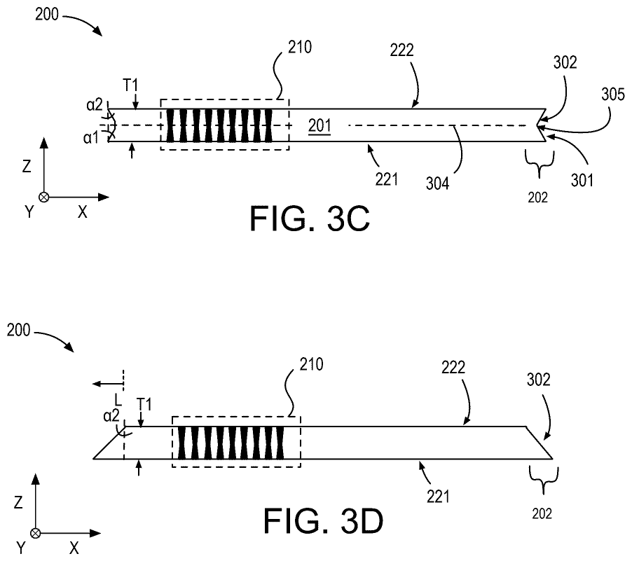

FIGS. 3A and 3B are plan and cross-sectional views of glass core panel 200 following edge profiling, in accordance with some embodiments. In this example, glass edge 202 has a first edge chamfer 301 intersecting bottom panel surface 221, and a second edge chamfer 302 intersecting top panel surface 222. In this example, edge chamfers 301 and 302 intersect at a ridge 303, which is coincident with centerline 304 at one-half thickness T1. However, depending on chamfer angles α1, α2 and maximum edge length L recessed by each of edge chamfers 301, 302, some intervening portion of edge 202 between edge chamfer 301 and 302 may remain orthogonal to surfaces 221 and/or 222.

In the expanded view of FIG. 3B, micro-roughening of edge chamfer 302 is further illustrated with an exemplary profile comprising topographic features 310 and intervening valleys. Edge chamfer 302 may have any surface roughness greater than the surface roughness of at least one of glass surfaces 221 and 222. In some embodiments, the average surface roughness of edge chamfer 302 is at least twice the average surface roughness of glass surface 222 and may be five, ten, or twenty times that of surface 222. In some embodiments where surface 222 has a low RMS surface roughness, for example <1 μm typical of a specular surface finish, edge chamfer 302 has a high RMS surface roughness, for example in the range of 1-10 μm. As used herein, average roughness (or center line average) is as described in ASME B46.1. Average roughness is the arithmetic average of the absolute values of profile height deviations from a mean line that is recorded for an evaluation length. Average roughness may be measured, for example, with a profilometer comprising a stylus that is traversed over a surface, or by atomic force microscopy (AFM). For edge chamfer 302 having a longitudinal length along a length L1, average roughness may be measured over a distance roughly 60-70% of L1 while remaining at about a centerline of a transverse width of edge chamfer 302 that is in a dimension substantially orthogonal to length L1.

Although edge roughening is illustrated in FIG. 3B for a glass edge that has also been macroscopically profiled, any roughening process may also be practiced on a glass panel edge that is not otherwise process from its as-received state. For example, edge roughening may be performed on glass panel 200 substantially as illustrated in FIG. 2A, 2B.

Although two edge chamfers 301, 302 are illustrated in FIG. 3B, edge profiling may introduce only one edge chamfer, for example intersecting only one of surfaces 221, 222, respectively. Edge chamfer angle (e.g., α1) may also vary with implementation. In some embodiments, edge chamfer 302 intersects glass surface 222 at an angle α2 having a magnitude of not more than 60°, and advantageously within a range of 30-60° with 45° being one specific example. As shown in FIG. 3B, edge chamfers 301, 302 have a positive slope from glass surfaces 221, 221 toward glass thickness centerline 304 and define a panel edge profile similar to the sidewall profile of TGVs 210, which also has a positive slope from glass surfaces 221, 222 toward panel thickness centerline 304.

FIG. 3C is a cross-sectional view of a glass core panel following edge profiling, in accordance with an alternative embodiment. In FIG. 3C, edge chamfers 301, 302 have negative chamfer angles α1, α2 meeting at a sidewall trough, trench, or recess 305. In the illustrated example, recess 305 is at thickness T1 centerline 304. Although negative, chamfer angles α1, α2 may again have a magnitude advantageously within a range of 30-60° and with 45° being one specific example. In FIG. 3C, edge chamfers 301, 302 have a negative slope from glass surfaces 221, 222 toward glass thickness centerline 304 and therefore define a panel edge profile opposite the sidewall profile of TGVs 210, which have a positive slope from glass surfaces 221, 222 to thickness centerline 304.

FIG. 3D illustrates an alternative embodiment with a one-sided chamfer where edge length L is so large for chamfer angle α2 that edge chamfer 302 intersects both glass surface 222 and glass surface 221, which may also be referred to as an edge “bevel.” In this example, chamfer (or bevel) angle α2 is positive and glass surface 221 has a larger surface area that glass surface 222. In alternative embodiments where angle α2 is negative, surface 222 has a larger surface area that surface 221.

Returning to FIG. 1, methods 100 continue at block 130, where a glass panel edge is chemically functionalized. Block 130 is illustrated in dashed line to emphasize surface chemical group functionalization is optional in methods 100. At block 130, an edge surface of a glass core panel may be terminated with any chemical functional group. In exemplary embodiments, a glass edge is terminated with one or more functional groups known to improve adhesion of an organic dielectric material. In some examples, a glass edge is exposed to one or more wet chemical or dry (plasma) chemical treatments that introduce active chemical functional groups promoting adhesion. Depending on the process(es) practiced to chemically terminate the glass edge, a mask material may be optionally applied to protect front and/or back surfaces of a glass core panel from the edge treatment. In some embodiments, at least the edge of a glass panel is exposed to an oxidation process suitable for terminating the glass with hydroxyl (—OH) groups. Relative to dangling bonds of silicon or glass dopants (e.g., aluminum), hydroxyl termination can improve surface adhesion, particularly with organic dielectric materials. In some examples, block 130 comprises a low-temperature oxidation process, such as an oxygen-based plasma energized by an RF or magnetron power source.

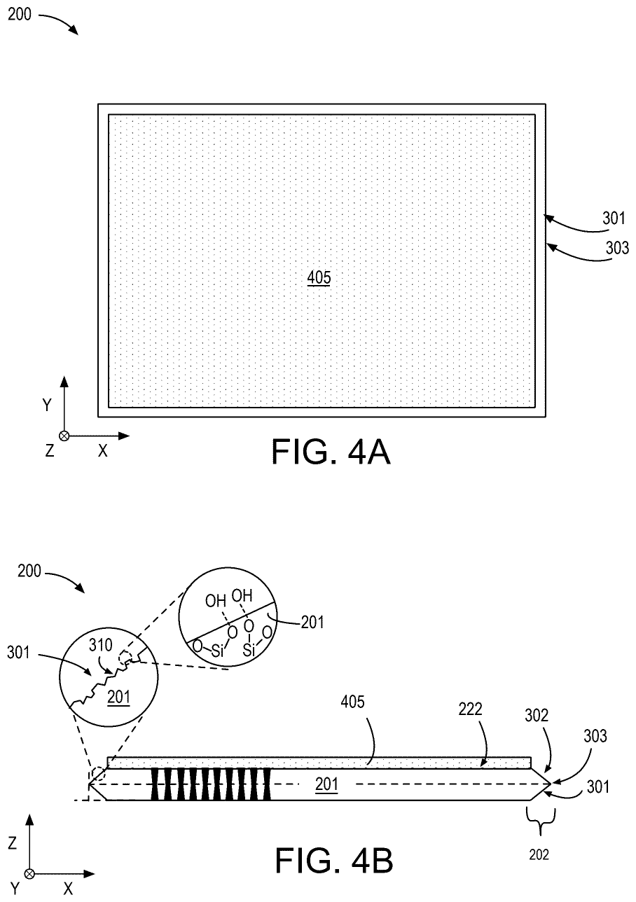

FIGS. 4A and 4B are plan and cross-sectional views of glass core panel 200 following a glass edge chemical surface treatment, in accordance with some embodiments further comprising glass edge chamfers 301, 302. In the example shown in FIGS. 4A and 4B, at least edge chamfer 302 has been further exposed to a chemical surface treatment. Edge chamfer 301 may also have been exposed to the same chemical surface treatment. In addition to a double-chamfer edge profile and surface roughness enhancement, glass core panel 200 further comprises hydroxyl termination on the glass surface of edge chamfer 302, as illustrated in the expanded view of FIG. 4B. In this example, a sacrificial mask material 405 also protects top glass surface 222 from hydroxyl termination. However, in other embodiments, top glass surface 222 is hydroxyl terminated along with chamfer edge(s) 302 (301), for example through exposure to an oxidizing plasma. For exemplary single-sided chemical treatments, terminal hydroxyl groups may be substantially absent from bottom glass surface 221 even when no masking is applied.

Returning to FIG. 1, methods 100 continue at block 140 where one or more edge-processed glass panels are positioned within a frame received as another preform at input 135. The frame preform may comprise one or more materials and have any dimensions compatible with that of the edge-processed glass panels. Any panel reconstitution known to be suitable for IC packaging may be practiced at block 140. In some embodiments, a pick-and-place machine positions one or more edge-processed glass panels within a frame so that the frame surrounds a perimeter of the panel.

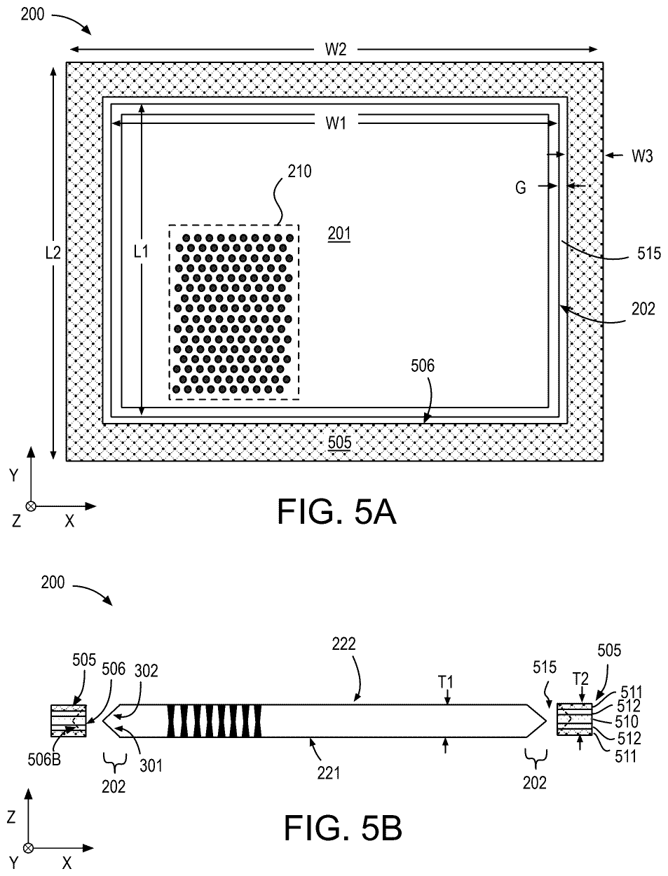

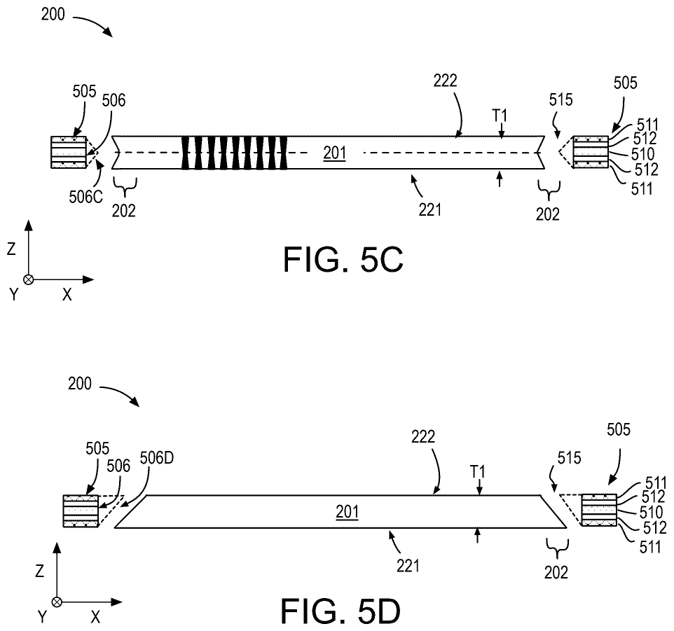

FIGS. 5A and 5B are plan and cross-sectional views illustrating a single glass core panel 200 within a perimeter frame 505, in accordance with some embodiments. In this example, perimeter frame 505 is a unitary body comprising one or more contiguous material layers. In some exemplary embodiments, perimeter frame 505 is a laminate of metallization and dielectric material, and may be any known CCL, for example.

As further illustrated in FIG. 5B, perimeter frame 505 may include a rigid core 510. For cored embodiments, a core may be an epoxy-based laminate (e.g., FR4), or silicon (e.g., monocrystalline) for example. Alternatively, perimeter frame 505 or may be coreless. In cored embodiments, layers of metallization 511 and layers of dielectric material 512 may have been built up on one or more sides of core 510 to reach a frame thickness T2 compatible with glass thickness T1. In coreless embodiments, frame 505 may consist of only metallization layers 511 and/or dielectric material layers 512.

If present within perimeter frame 505, dielectric material 512 may be, for example, an organic dielectric, such as, an epoxy resin, phenolic-glass, or a resinous film such as the GX-series films commercially available from Ajinomoto Fine-Techno Co., Inc. (ABF). Dielectric material 512 may comprise epoxy resins (e.g., an acrylate of novolac such as epoxy phenol novolacs (EPN) or epoxy cresol novolacs (ECN)). In other examples, dielectric material 512 includes aliphatic epoxy resin, which may be monofunctional (e.g., dodecanol glycidyl ether), difunctional (butanediol diglycidyl ether), or have higher functionality (e.g., trimethylolpropane triglycidyl ether).

If present within perimeter frame 505, metallization layers 511 may comprise any metal known to be suitable for electrical interconnection, routing, and/or redistribution within an IC die package and/or IC die. Metallization layers 511 may be predominantly Cu, for example, or another metal that may be similarly plated or otherwise deposited (e.g., by physical vapor deposition) at temperatures compatible with dielectric material 512 and/or core 510.

Perimeter frame 505 has an exterior hybrid panel length L2 and width W2, which are larger than a glass core panel length L1 and width W1, respectively, by an amount sufficient to accommodate a frame width W3 and to space an interior frame edge 506 apart from glass panel edge 202 by a gap 515 having a non-zero distance G. In exemplary CCL frame embodiments, W3 may be 1-3 cm while gap distance G may be in the range of 0.5-2 mm. In the example illustrated, a perimeter of a single glass panel 200 is surrounded by perimeter frame 505. As received, perimeter frame may have any thickness T2, but in some embodiments frame thickness T2 is substantially equal to glass thickness T1.

Interior frame edge 506 may be substantially orthogonal to a glass panel surfaces 221, 222. However, interior frame edge 506 may be defined through mechanical milling (e.g., sawing and/or cutting), laser ablation, etc. to have any edge profile. In some embodiments, interior frame edge 506 comprises a protrusion or recess adjacent to panel edge 202. For example, as illustrated in dashed line, an interior frame edge 506B may have a recess that is complementary to glass edge chamfers 301, 302 and therefore substantially maintains gap distance G over glass thickness T1.

FIGS. 5C and 5D are plan and cross-sectional views illustrating a single glass core panel within a perimeter frame 505, in accordance with alternative panel edge profiles introduced in FIGS. 3C and 3D, respectively. As shown in FIG. 5C, for a panel profile with negative edge chamfers defining an edge recess or trench, perimeter frame 505 may again have an interior edge 506 that is substantially normal to glass surfaces 221, 222. Alternatively, as illustrated by dashed line, an interior edge 506C may be cut to have a ridge that is complementary to panel edge chamfers and therefore again substantially maintains gap distance G over glass thickness T1. For the glass edge bevel illustrated in FIG. 5D, perimeter frame 505 may again have an interior edge 506 that is substantially normal to glass surfaces 221, 222. Alternatively, as illustrated by dashed line, an interior edge 506D may be cut to have an inverse edge bevel that is complementary to the glass edge bevel so that gap 515 is substantially constant over glass thickness T1.

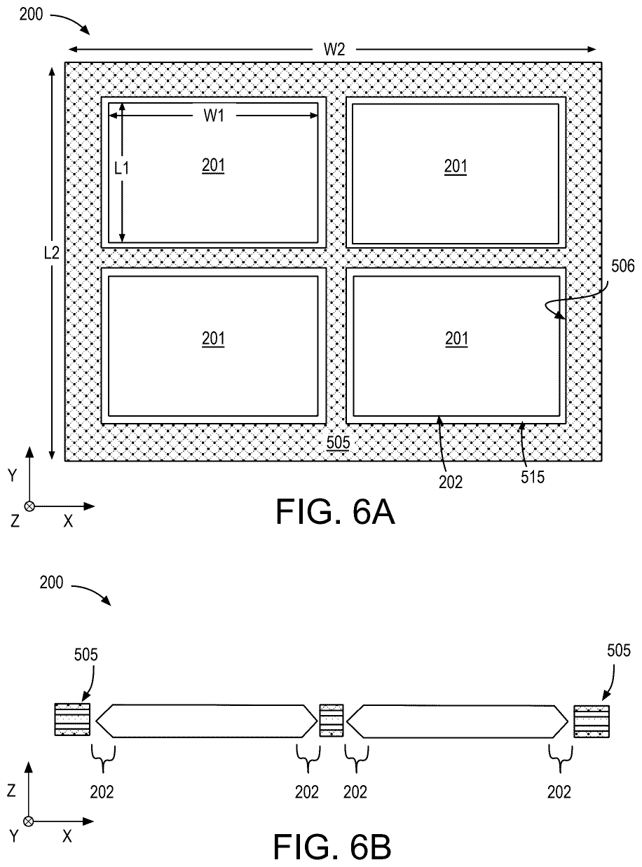

FIGS. 6A and 6B are plan and cross-sectional views illustrating quarter glass core panels reconstituted within a quarter panel frame, in accordance with some embodiments where four glass core panels are positioned within a contiguous frame 505. Perimeter frame 505 again has exterior hybrid panel length L2 and exterior width W2 that can be readily handled by reconstituted panel processing equipment. However, frame 505 has four interior edges 506, each surrounding a glass core panel 201 and spaced apart from glass edge 202 by gap 515. For embodiments where L2 and W2 are each 500-550 mm, glass core panel length L1 and width W1 may each be 100-120 mm, for example.

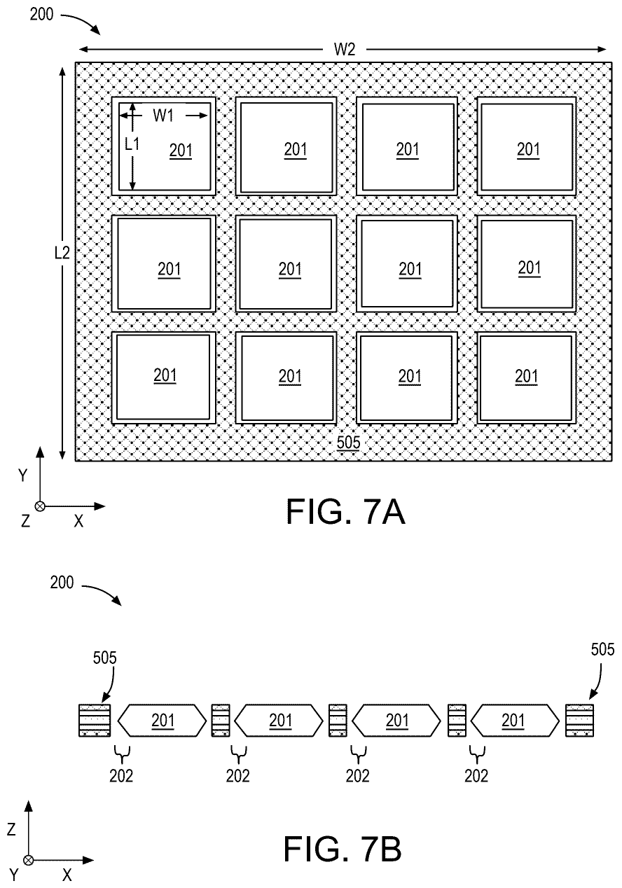

FIGS. 7A and 7B are plan and cross-sectional views illustrating glass core panel units reconstituted within a multi-unit frame accommodating 16 glass core panel units having dimensions L1, W1 that are sufficiently small to permit frame 505 to have an exterior hybrid panel length L2 and exterior hybrid panel width W2 that can be readily handled by reconstituted panel processing equipment. For embodiments where L2 and W2 are each 500-550 mm, L1 and W1 may each be less than 100 mm, for example.

Returning to FIG. 1, methods 100 continue at block 150 where one or more glass core panels are adhered to a perimeter frame with a dielectric material. In some embodiments, a dry film is applied (e.g., laminated) over both the frame and the glass core panel(s). In other embodiments, a flowable epoxy is applied over both the frame and the glass core panel(s) and subsequently cured. Application of the dielectric material advantageously places the dielectric material in direct contact with at least the glass core panel edge. Application of the dielectric material may also place the dielectric material in direct contact with an interior edge of the frame.

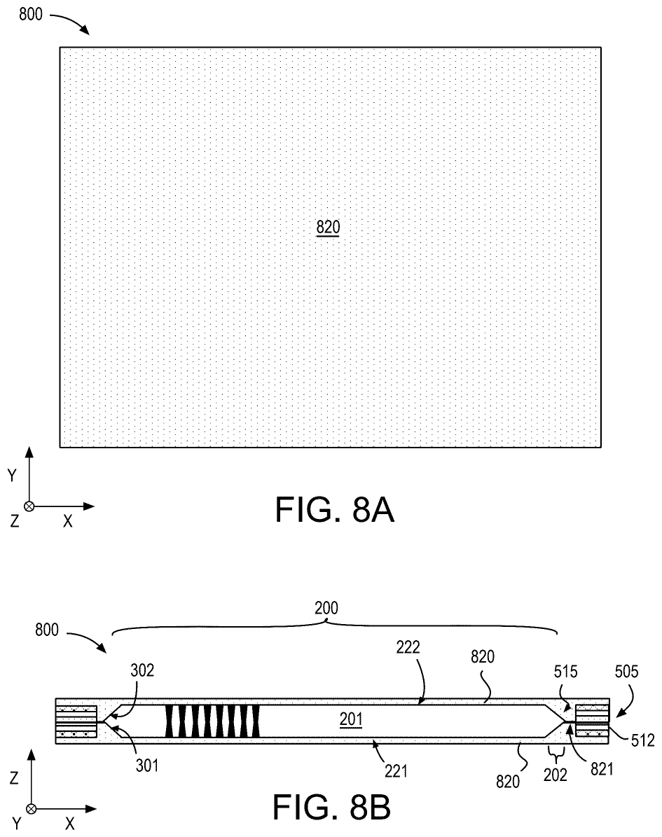

FIGS. 8A and 8B are plan and cross-sectional views illustrating a hybrid panel 800 following lamination of a single glass core panel 201 and frame 505, in accordance with some embodiments. As shown, a dielectric material layer 820 has been applied to glass surface 222. Dielectric material layer 820 extends over at least a portion of frame 505, at least partially backfills gap 515, and makes direct contact with edge chamfer 302. Another dielectric material layer 820 has been applied to glass surface 221. This dielectric material layer 820 also extends over at least a portion of frame 505, at least partially backfills gap 515, and makes direct contact with edge chamfer 302. Within gap 515 the two dielectric material layers 820 meet at an interface 821. The composition of dielectric material layers 820 may vary with implementation. In some embodiments, dielectric material layers 820 comprise an organic dielectric material, such as any of the those materials listed above for dielectric material 512. For example, layers of ABF may be applied as dielectric material layers 820, sandwiching glass core panel 200 and frame 505 there between.

Returning to FIG. 1, methods 100 end at output 160 where hybrid panel build up is completed. Any IC die attachment may further be practiced at output 160 or downstream of methods 100 as embodiments are not limited in this respect. Panel build up may be according to any techniques known to be suitable for advanced package substrates. For example, dielectric material layers may be patterned and electrically conductive materials may be deposited upon the patterned dielectric surface to form a routing or redistribution metallization layers. Conductive material layers, for example comprising predominantly Cu, may be deposited by any known technique, such as plating.

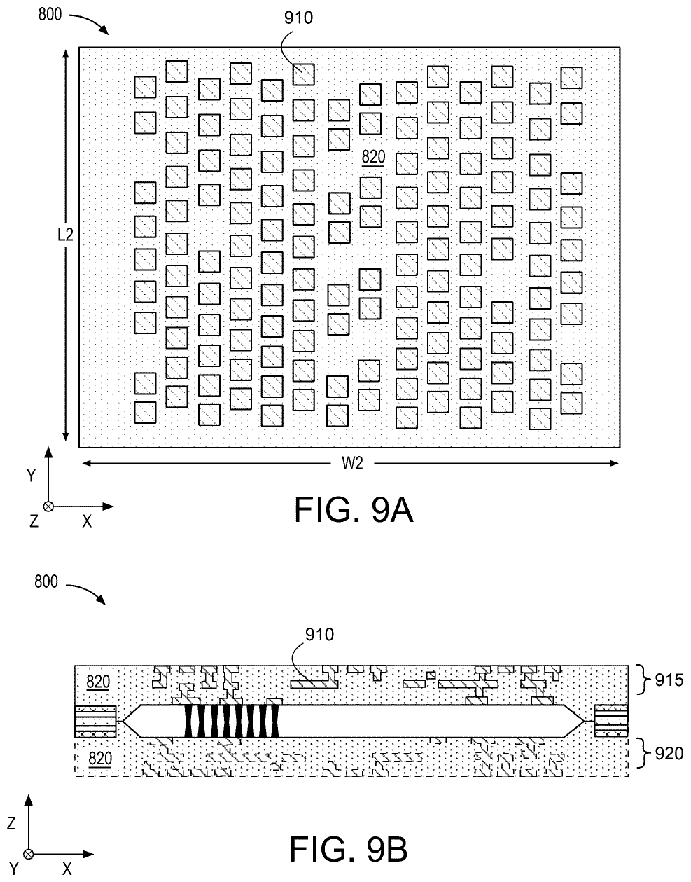

FIGS. 9A and 9B are plan and cross-sectional views illustrating build-up of an RDL structure 915 on a first (e.g., front) side of hybrid panel 800, in accordance with some embodiments. RDL structure 915 includes a plurality of levels of metallization features 910 embedded within one or more organic dielectric materials 820. In some further embodiments, another RDL structure 920 may be formed on a second (e.g., back) side of hybrid panel 800. RDL structure 920 is illustrated in dashed line to emphasize hybrid panel build-up may be single-sided.

Following hybrid panel build up, a hybrid panel may be singulated into discrete glass-core package substrates. Depending on the structure of the hybrid panel, one or more glass-core package substrates may be formed from a single hybrid panel. For example, individual glass core package substrates may be singulated from any of the exemplary hybrid panels illustrated in FIG. 5A, 6A or 7A. A single glass core package substrate may evolve from a single hybrid panel, or a plurality (e.g., 4, 16, etc.) glass core package substrates may evolve from a single hybrid panel.

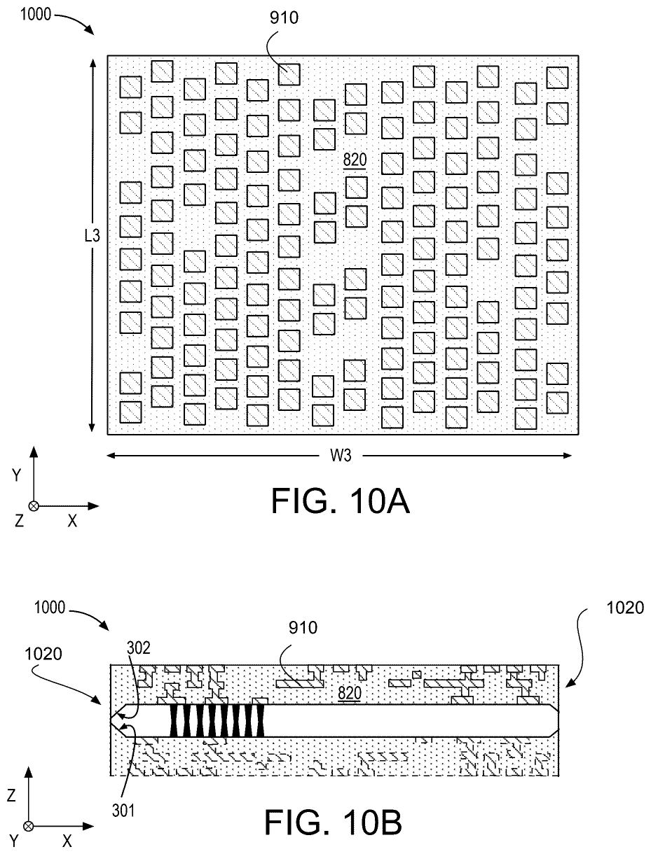

FIGS. 10A and 10B are plan and cross-sectional views illustrating singulation of hybrid panel 800 (illustrated in FIG. 9A, 9B) into a glass-core package substrate 1000. In this example, glass-core package substrate 1000 has been cut down along a package substrate edge 1020, eliminating a perimeter of the hybrid panel comprising the frame. Package substrate 1000 therefore has a length L3 that is no larger than glass core panel length L1 and a width W3 that is no larger than glass core panel width W1 (FIG. 2A). Although length L3 and width W3 may be substantially smaller than glass core panel length L1 and width W1, one or more edge chamfers 301, 302 may be retained along one or more package substrate edges 1020. Accordingly, various attributes of a glass core panel edge may remain as permanent features of glass core package substrate 1000.

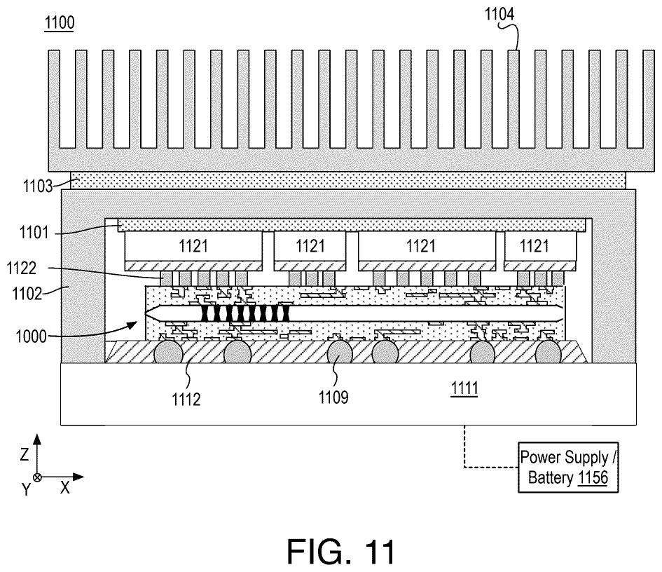

FIG. 11 is a cross-sectional view illustrating a microelectronic device assembly 1100, which includes glass core package substrate 1000, in accordance with some embodiments. Microelectronic device assembly 1100 includes a plurality of IC dies 1121 joined to package substrate 1000 with die-level interconnects 1122. However, any single IC die, 3D stacked multichip device, multi-chip composite structure, or the like may be similarly assembled or directly bonded to glass core package substrate 1000.

A thermal interface material (TIM) 1101 is between IC dies 1121 and a heat spreader and/or lid 1102, which extends beyond a perimeter of package substrate 1000, and is mounted to board 1111. Another TIM 1103 is between heat spreader 1102 and a thermal dissipation device 1104, which may be a heat sink, heat pipe or other thermal solution.

Build up on a second side of package substrate 1000 is electrically coupled to a board 1111 with package-level interconnects 1109 (e.g., solder features) that may be at least partially surrounded by underfill material 1112. Board 1111 may include any suitable substrate such as a motherboard, interposer, or the like. Microelectronic device assembly 1100 is coupled to a power supply 1156, for example through one or more of board 1111 and glass core package substrate 1000. Power supply 1156 may include a battery and multi-rail power supply circuitry, such as a switching supply with a voltage converter, etc.

Glass core package substrate 1000 may comprise one or more of the structural features described elsewhere herein. For example, package substrate 1000 may include a layer of bulk glass having a profiled and/or chemically terminated edge as described above in the context of glass core panel 200 from which package substrate 1000 evolved.

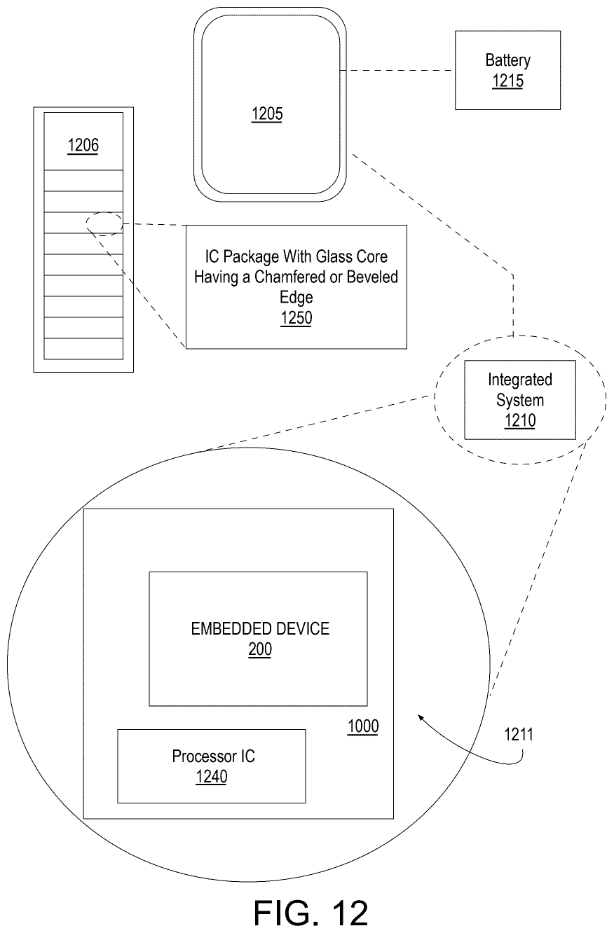

The various glass core edge features, and methods of forming such features, described herein may be integrated into a wide variety of IC packages and systems that include such IC packages. FIG. 12 illustrates a system in which a mobile computing platform 1205 and/or a data server machine 1206 includes a packaged IC die 1250 comprising a glass core package substrate in accordance with one or more of the embodiments described elsewhere herein. The server machine 1206 may be any commercial server, for example including any number of high-performance computing platforms within a rack and networked together for electronic data processing. The mobile computing platform 1205 may be any portable device configured for each of electronic data display, electronic data processing, wireless electronic data transmission, or the like. For example, the mobile computing platform 1205 may be any of a tablet, a smart phone, laptop computer, etc., and may include a display screen (e.g., a capacitive, inductive, resistive, or optical touchscreen), an IC die package integrated system 1210, and a battery 1215.

Whether disposed within the integrated system 1210 further illustrated in the expanded view 1211, or as a stand-alone chip within the server machine 1206, packaged IC die 1250 may include memory circuitry (e.g., RAM), and/or a logic circuitry (e.g., a microprocessor, a multi-core microprocessor, graphics processor, or the like). At least one of these circuitries comprises a glass cored package substrate including one or more edge feature in accordance with one or more embodiments described elsewhere herein. Integrated system 1210 may include glass core package substrate 1000 that hosts one or more ICs, such as a processor IC 1240. Package substrate 1000 may further host an embedded device, such as a MIM capacitor array that is at least partially embedded within the glass core of substrate 1000.

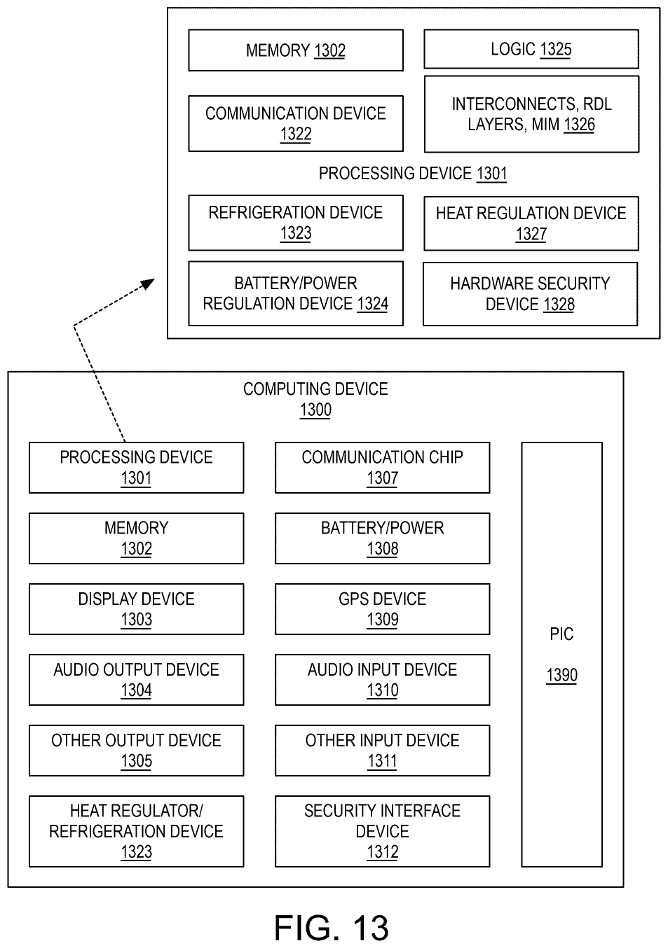

FIG. 13 is a block diagram of a computing device 1300 in accordance with some embodiments. For example, one or more components of computing device 1300 may include any of the glass core structures discussed elsewhere herein. A number of components are illustrated in FIG. 13, but any one or more of these components may be omitted or duplicated, as suitable for the application. In some embodiments, some of the components included in computing device 1300 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1300 may not include one or more of the components illustrated in FIG. 13, but computing device 1300 may include interface circuitry for coupling to the one or more components. For example, computing device 1300 may not include a display device 1303, but may include display device interface circuitry (e.g., a connector and driver circuitry) to which display device 1303 may be coupled.

Computing device 1300 may include a processing device 1301 (e.g., one or more processing devices). As used herein, the term processing device or processor indicates a device that processes electronic data from registers and/or memory to transform that electronic data into other electronic data that may be stored in registers and/or memory. Processing device 1301 may include a memory 1302, a communication device 1322, a refrigeration/active cooling device 1323, a battery/power regulation device 1324, logic 1325, interconnects 1326, a heat regulation device 1327, and a hardware security device 1328.

Processing device 1301 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 1301 may include a memory 1302, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1301 shares a package with memory 1302. This memory may be used as cache memory and may include embedded dynamic random-access memory (eDRAM) or spin transfer torque magnetic random-access memory (STT-M RAM).

Computing device 1300 may include a heat regulation/refrigeration device 1323. Heat regulation/refrigeration device 1323 may maintain processing device 1301 (and/or other components of computing device 1300) at a predetermined low temperature during operation. This predetermined low temperature may be any temperature discussed elsewhere herein.

In some embodiments, computing device 1300 may include a communication chip 1307 (e.g., one or more communication chips). For example, the communication chip 1307 may be configured for managing wireless communications for the transfer of data to and from computing device 1300. The term “wireless” and its derivatives may be used to describe circuits, devices, systems, methods, techniques, communications channels, etc., that may communicate data through the use of modulated electromagnetic radiation through a nonsolid medium.

Computing device 1300 includes a PIC 1390, for example having a photonic integrated WDM source circuit. PIC 1390 may facilitate communication between one or more instances of processing device 1301 and/or one or more instances of memory 1302, for example.

Computing device 1300 may include battery/power circuitry 1308. Battery/power circuitry 1308 may include one or more energy storage devices (e.g., batteries or capacitors) and/or circuitry for coupling components of computing device 1300 to an energy source separate from computing device 1300 (e.g., AC line power).

Computing device 1300 may include a display device 1303 (or corresponding interface circuitry, as discussed above). Display device 1303 may include any visual indicators, such as a heads-up display, a computer monitor, a projector, a touchscreen display, a liquid crystal display (LCD), a light-emitting diode display, or a flat panel display, for example.

Computing device 1300 may include an audio output device 1304 (or corresponding interface circuitry, as discussed above). Audio output device 1304 may include any device that generates an audible indicator, such as speakers, headsets, or earbuds, for example.

Computing device 1300 may include an audio input device 1310 (or corresponding interface circuitry, as discussed above). Audio input device 1310 may include any device that generates a signal representative of a sound, such as microphones, microphone arrays, or digital instruments (e.g., instruments having a musical instrument digital interface (MIDI) output).

Computing device 1300 may include a global positioning system (GPS) device 1309 (or corresponding interface circuitry, as discussed above). GPS device 1309 may be in communication with a satellite-based system and may receive a location of computing device 1300.

Computing device 1300 may include another output device 1305 (or corresponding interface circuitry, as discussed above). Examples include an audio codec, a video codec, a printer, a wired or wireless transmitter for providing information to other devices, or an additional storage device.

Computing device 1300 may include another input device 1311 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1300 may include a security interface device 1312. Security interface device 1312 may include any device that provides security measures for computing device 1300 such as intrusion detection, biometric validation, security encode or decode, managing access lists, malware detection, or spyware detection.

Computing device 1300, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that embodiments described herein may be practiced with modification and alteration without departing from the scope of the appended claims. For example, the above embodiments may include specific combinations of features as further provided below.

In first examples, an apparatus comprises a glass core panel comprising an edge bevel or chamfer, and a plurality of metal features extending through a thickness of the glass core panel.

In second examples, for any of the first examples the glass core panel has a first edge chamfer intersecting the top surface of the glass core panel, and the glass core panel comprises a second edge chamfer intersecting a bottom surface of the glass core panel.

In third examples, for any of the first through second examples the apparatus further comprises an organic dielectric material over a top surface of the glass core panel and in direct contact with the edge bevel or chamfer.

In fourth examples, for any of the third examples, the apparatus further comprises a frame surrounding the glass core panel, and wherein the organic dielectric material is between the edge bevel or chamfer and an interior edge of the frame.

In fifth examples, for any of the fourth examples the glass core panel has a first edge chamfer intersecting the top surface of the glass core panel, the glass core panel comprises a second edge chamfer intersecting a bottom surface of the glass core panel, and the organic dielectric material is within a first space between the first edge chamfer, and the frame and is also within a second space between the second edge chamfer and the frame.

In sixth examples, for any of the fourth through fifth examples the frame comprises a metal-clad laminate.

In seventh examples, for any of the sixth examples the interior edge of the frame comprises a recess or protrusion adjacent to the edge bevel or chamfer of the glass core panel.

In eighth examples, for any of the seventh examples the recess comprises a v-groove between a top and bottom surface of the frame.

In ninth examples, for any of the first through eighth examples the edge bevel or chamfer intersects the top surface at an angle of not more than 60°.

In tenth examples, for any of the first through ninth examples a surface of the edge bevel or chamfer has greater average surface roughness than the top surface of the glass panel.

In eleventh examples, for any of the tenth examples the beveled or chamfered edge has a profile roughness of at least 10 μm.

In twelfth examples, for any of the fourth through eleventh examples the glass panel has a length exceeding 120 mm.

In thirteenth examples, for any of the twelfth examples the frame has a perimeter width of less than 5 cm and where the glass panel has a length exceeding 450 mm.

In fourteenth examples, an apparatus comprises an integrated circuit (IC) die, and a package substrate coupled to the IC die. The package substrate comprises a glass core, the glass core comprising conductive vias extending through a thickness of the glass core, an organic dielectric material over a top surface of the glass core, and a level of routing metallization features over the top surface of the glass core. The routing metallization features are coupled to the vias, and at least a portion of the glass core has an edge, non-orthogonal to the top surface of the glass core.

In fifteenth examples, for any of the fourteenth examples the organic dielectric material is in contact with an edge bevel or chamfer of the glass core.

In sixteenth examples, for any of the fourteenth through fifteenth examples the edge of the glass core has a profile roughness exceeding that of the top surface of the glass core.

In seventeenth examples, a method comprises receiving a glass panel with a planar top surface, profiling an edge of the glass panel to be non-orthogonal to the top surface, forming a hybrid panel by joining the glass panel with a frame that surrounds a perimeter of the glass panel, and forming a level of metallization features over a top surface of the glass panel and coupled to vias extending through the glass panel by processing the hybrid panel through one or more semi-additive processes (SAP).

In eighteenth examples, for any of the seventeenth examples profiling the edge comprises at least one of exposing an outer perimeter of the glass panel to laser energy or a wet chemical.

In nineteenth examples, for any of the seventeenth through eighteenth examples the method further comprises chemically treating the edge of the glass panel to terminate the surface with functional surface groups that improve adhesion with an organic dielectric layer.

In twentieth examples, chemical treating the edge comprises exposing the edge of the glass panel to a plasma of a source gas and wherein the functional surface groups comprise a hydroxyl group.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims.

What is claimed is:

1. An apparatus, comprising:
a glass core panel comprising an edge bevel or chamfer; and
a plurality of metal interconnect features to electrically couple with an integrated circuit device, wherein individual ones of the metal interconnect features extend through a thickness of the glass core panel.

2. The apparatus of claim 1, wherein:
the glass core panel has a first edge chamfer intersecting a top surface of the glass core panel; and
the glass core panel comprises a second edge chamfer intersecting a bottom surface of the glass core panel.

3. The apparatus of claim 1, further comprising an organic dielectric material over a top surface of the glass core panel and in direct contact with the edge bevel or chamfer.

4. The apparatus of claim 3, further comprising a frame surrounding the glass core panel, and wherein the organic dielectric material is between the edge bevel or chamfer and an interior edge of the frame.

5. The apparatus of claim 4, wherein:
the glass core panel has a first edge chamfer intersecting the top surface of the glass core panel;
the glass core panel comprises a second edge chamfer intersecting a bottom surface of the glass core panel; and
the organic dielectric material is within a first space between the first edge chamfer, and the frame and is also within a second space between the second edge chamfer and the frame.

6. The apparatus of claim 4, wherein the frame comprises a metal-clad laminate.

7. The apparatus of claim 6, wherein the interior edge of the frame comprises a recess or protrusion adjacent to the edge bevel or chamfer of the glass core panel.

8. The apparatus of claim 7, wherein the recess comprises a v-groove between a top and bottom surface of the frame.

9. The apparatus of claim 1, wherein the edge bevel or chamfer intersects a top surface of the glass core panel at an angle of not more than 60°.

10. The apparatus of claim 1, wherein a surface of the edge bevel or chamfer has greater average surface roughness than a top surface of the glass core panel.

11. The apparatus of claim 10, wherein the beveled or chamfered edge has a profile roughness of at least 10 μm.

12. The apparatus of claim 4, wherein the glass core panel has a length exceeding 120 mm.

13. The apparatus of claim 12, wherein the frame has a perimeter width of less than 5 cm and where the glass core panel has a length exceeding 450 mm.

14. An apparatus, comprising
an integrated circuit (IC) die; and
a package substrate coupled to the IC die, wherein the package substrate comprises a glass core, the glass core comprising:
a plurality of conductive vias extending through a thickness of the glass core;
an organic dielectric material over a top surface of the glass core; and
a level of routing metallization features over the top surface of the glass core, the routing metallization features coupled to the vias, wherein at least a portion of the glass core has an edge, non-orthogonal to the top surface of the glass core.

15. The apparatus of claim 14, wherein the organic dielectric material is in contact with an edge bevel or chamfer of the glass core.

16. The apparatus of claim 14, wherein the edge of the glass core has a profile roughness exceeding that of the top surface of the glass core.

17. A method comprising:
receiving a glass core preform with a planar top surface;
profiling an edge of the glass core to be non-orthogonal to the top surface;
forming a hybrid panel by joining the glass core preform with a frame that surrounds a perimeter of the glass core preform; and
forming a level of metallization features over a top surface of the glass core preform and coupled to vias extending through the glass core by processing the hybrid panel through one or more material deposition and patterning processes.

18. The method of claim 17, wherein profiling the edge comprises at least one of exposing an outer perimeter of the glass core preform to laser energy or a wet chemical.

19. The method of claim 17, further comprising chemically treating the edge of the glass core preform to terminate the edge with functional surface groups that improve adhesion with an organic dielectric layer.

20. The method of claim 19, wherein chemical treating the edge comprises exposing the edge of the glass core preform to a plasma of a source gas and wherein the functional surface groups comprise a hydroxyl group.
